(19) United States
(12) Patent Application Publication
(10) Pub. No.: US 2025/0323228 A1
(43) Pub. Date: Oct. 16, 2025

(54) STACKED HIGH-POWER RF SWITCH

(71) Applicant: GlobalFoundries U.S. Inc., Malta, NY (US)

(72) Inventors: Santosh Kumar GEDELA, Komarapalayam (IN); Venkata Narayana Rao VANUKURU, Bangalore (IN)

(21) Appl. No.: 18/635,547

(22) Filed: Apr. 15, 2024

(51) Int. Cl. H01L 25/16; H01L 23/00

(52) U.S. Cl. CPC H01L 25/16; H01L 24/29; H01L 24/32; H01L 2224/29186; H01L 2224/32145; H01L 2924/0533; H01L 2924/0534; H01L 2924/05341; H01L 2924/05342; H01L 2924/0535; H01L 2924/05432; H01L 2924/0545; H01L 2924/0549

(57) ABSTRACT

The present disclosure relates to semiconductor structures and, more particularly, to a stacked high-power radio frequency (RF) switch and methods of manufacture. The structure includes: a top substrate having at least one top transistor and metal wiring structures; and a bottom substrate having at least one bottom transistor and metal wiring structure. The bottom substrate is attached to the top substrate with the at least one top transistor being electrically connected to the at least one bottom transistor. A portion of the metal wiring structures of the top substrate and a portion of the metal wiring structures of the bottom substrate being at least one shared capacitor between the at least one top transistor and the at least one bottom transistor. Airgaps may be formed above the transistor.

### BACKGROUND

The present disclosure relates to semiconductor structures and, more particularly, to a stacked high-power radio frequency (RF) switch and methods of manufacture.

A tuner includes a stack of transistors in series, with capacitors on top of the transistors. The capacitors are compensating capacitors which are required to compensate for the parasitics of the device. For example, the breakdown voltage of the tuner will increase as voltage travels through the stack of transistors in series. This results in Pmax becoming saturated. To compensate for these phenomena, larger capacitors are required at the front end of the stack of transistors to provide the needed voltage swing for the outer transistors in the stack of transistors. The size of the capacitors can be decreased along the stack of transistors. These capacitors, though, will increase the overall size of the tuner.

### SUMMARY

In an aspect of the disclosure, a structure comprises: a top substrate comprising at least one top transistor and metal wiring structures; and a bottom substrate comprising at least one bottom transistor and metal wiring structures, the bottom substrate being attached to the top substrate with the at least one top transistor being electrically connected to the at least one bottom transistor and a portion of the metal wiring structures of the top substrate and a portion of the metal wiring structures of the bottom substrate comprising at least one shared capacitor between the at least one top transistor and the at least one bottom transistor.

In an aspect of the disclosure, a structure comprises: a top substrate comprising a plurality of top transistors in series, each of the top transistors having a source region and a drain region; a bottom substrate comprising a plurality of bottom transistors in series, each of the bottom transistors having a source region and a drain region; and a plurality of capacitors electrically shared between the top transistors and the bottom transistors.

In an aspect of the disclosure, a method comprises: forming a top substrate comprising at least one top transistor and metal wiring structures; forming a bottom substrate comprising at least one bottom transistor and metal wiring structures; and attaching the bottom substrate to the top substrate with the at least one top transistor being electrically connected to the at least one bottom transistor and a portion of the metal wiring structures of the top substrate and a portion of the metal wiring structures of the bottom substrate forming at least one shared capacitor between the at least one top transistor and the at least one bottom transistor.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a circuit diagram in accordance with aspects of the present disclosure.

FIG. 2 shows a representative structure of the circuit diagram of FIG. 1 and respective fabrication processes in accordance with aspects of the present disclosure.

### DETAILED DESCRIPTION

The present disclosure relates to semiconductor structures and, more particularly, to a stacked high-power radio frequency (RF) switch and methods of manufacture. In embodiments, the stacked switch may be representative of a tuner shared between a top substrate (wafer) and a bottom substrate (wafer). In embodiments, the stacked switch comprises a top substrate attached (e.g., bonded) to a bottom substrate with at least one capacitor electrically connected between transistors of the top substrate and the bottom substrate. Advantageously, the switch and/or tuner may provide higher voltage handling with an extremely small footprint, e.g., greater than 65% area savings compared to conventional stacked devices.

In more specific embodiments, the switch is a stack of switches comprising transistors shared between a top substrate (also known as a wafer) and a bottom substrate. In embodiments, the bottom substrate may be a high-resistivity semiconductor substrate and the top substrate may be a low-resistivity semiconductor substrate. The top substrate and the bottom substrate may be bonded together by metal vias, which electrically connects source and drain regions, respectively, of the transistors of the top substrate and the bottom substrate. In embodiments, the bottom substrate may include airgaps; whereas the top substrate may be devoid of airgaps. A plurality of metal-oxide-metal compensating capacitors may be provided and electrically connected between transistors of the top substrate and the bottom substrate. In embodiments, the capacitors may comprise high-dielectric material, low-k dielectric or combinations thereof, depending on the desired performance parameters. For example, high-k dielectric material may be used for the first, inner capacitors and low-k dielectric material for capacitors in the outer regions.

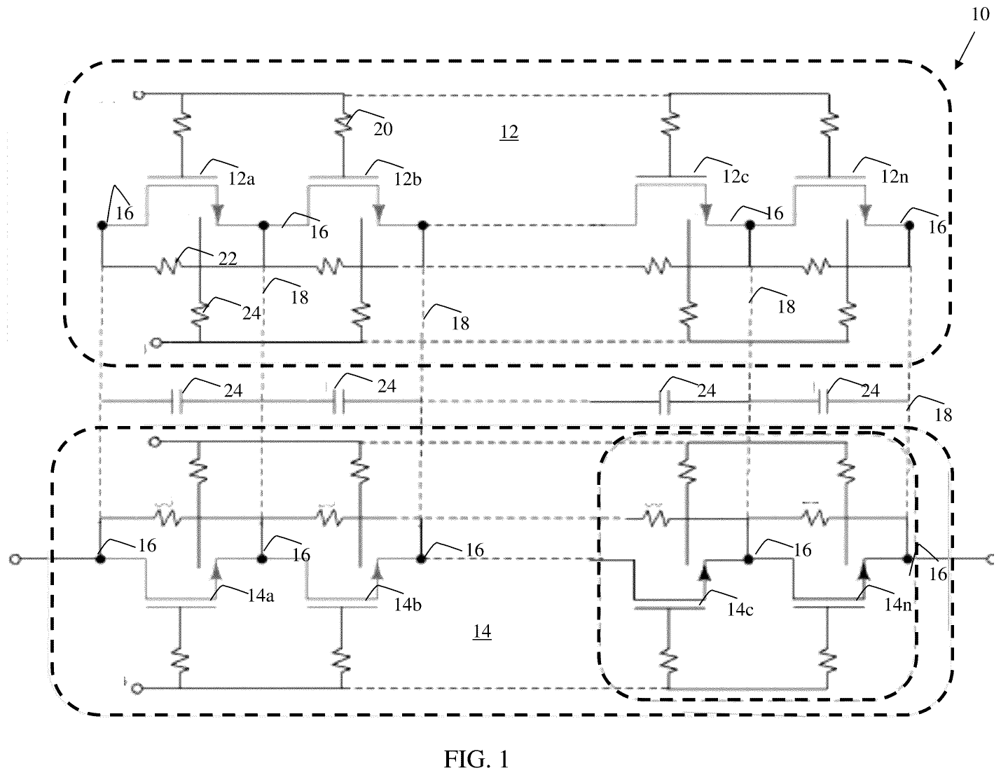

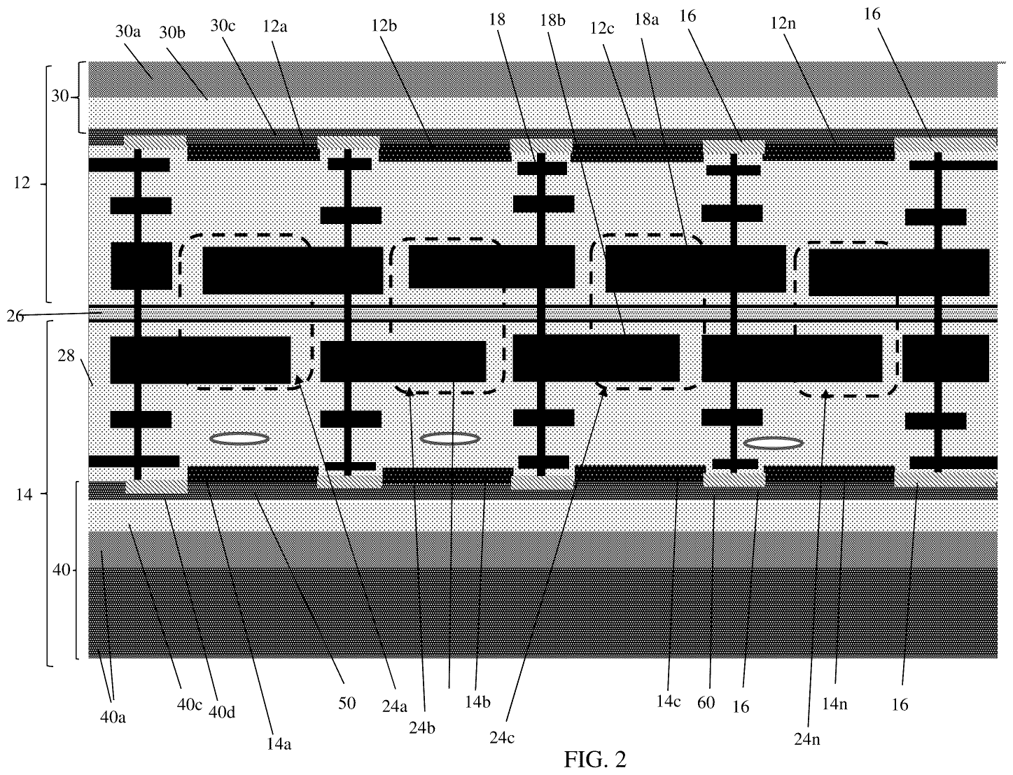

FIG. 1 shows a circuit diagram of a switch and/or tuner in accordance with aspects of the present disclosure. In embodiments, the circuit diagram 10 comprises a stack of two separate circuits: a top circuit 12 and a bottom circuit 14. In embodiments, the top circuit 12 may be provided on a top substrate attached (e.g., bonded) to the bottom circuit 14 provided on a bottom substrate as described in more detail with respect to FIG. 2. In embodiments, the stack of circuits 12, 14 may comprise a tuner where part of the tuner is provided on each of the circuits 12, 14.

The top circuit 12 includes a plurality of transistors 12a, 12b, 12c, 12n, in series. Similarly, the bottom circuit 14 includes a transistors 14a, 14b, 14c, 14n, in series. The transistors 12a, 12b, 12c, 12n and transistors 14a, 14b, 14c, 14n are electrically connected together at their respective source regions and drain regions (represented at reference numeral 16) by metallization features 18, e.g., wiring structures. The metallization features 18 may comprise a plurality of different wiring layers and interconnect structures as should be understood by those of skill in the art and as shown in more detail with respect to FIG. 2. Also, as should be understood by those of ordinary skill in the art, the transistors 12a, 12b, 12c, 12n, 14a, 14b, 14c, 14n comprise gate structures which exhibit a gate resistance 20, source/drain resistance 22 and body resistance 24 such that no further explanation is required for a complete understanding of the present disclosure.

FIG. 1 further shows a plurality of capacitors 24. In embodiments, the capacitors 24 may be compensating metal-oxide-metal capacitors. The capacitors 24 are provided between the top circuit 12 and the bottom circuit 14 and, more specifically, between the top substrate comprising the top circuit 12 and the bottom substrate comprising the bottom circuit 14. In embodiments, the plurality of capacitors 24 are provided between the respective transistors 12a, 14a, 12b, 14b, 12c, 14c, 12n, 14n and, more specifically, are electrically connected to the source/drain regions 16 of the respective transistors 12a, 14a, 12b, 14b, 12c, 14c, and 12n, 14n by the metallization features 18. In embodiments, the capacitor plates of the capacitors 24 may comprise overlapping wiring layers of the metallization features 18 of the top circuit 12 and the bottom circuit 14 with dielectric material therebetween.

FIG. 2 shows a representative structure of the circuit diagram of FIG. 1 and respective fabrication processes in accordance with aspects of the present disclosure. In embodiments, the structure 10 comprises a stack of two circuits: a top circuit 12 electrically connecting to a bottom circuit 14. In embodiments, the top circuit 12 is provided on a top substrate 30 and the bottom circuit 14 is provided on a bottom substrate 40. In embodiments, the top substrate 30 and bottom substrate 40 may be attached, e.g., bonded, together by insulator material 26 and metal vias as described in more detail herein.

The top substrate 30 may be a low-resistivity substrate and the bottom substrate 40 may be a high-resistivity substrate (e.g., up to 10,000 ohm-cm); although other combinations are contemplated herein, e.g., top and bottom substrates being both low resistivity, both high-resistivity or any combination thereof. By way of example, a high resistivity substate may be designed to handle high voltages, e.g., about 80V to 100V and a low resistivity substrate may be designed to handle low voltages, e.g., about 20V. The top substrate 30 may be floating, hence only requiring a low-resistivity substrate. Also, as should be understood by those of skill in the art, the top substrate 30 and the bottom substrate 40 may each be representative of a single chip. The top circuit 12 and the bottom circuit 14 may form a tuner structure comprising the stacked chips.

The top substrate 30 and the bottom substrate 40 may comprise semiconductor on insulator substrate (SOI) technology. For both the top substrate 30 and the bottom substrate 40, the SOI substrate, from bottom to top, includes a respective handle substrate 30a, 40a, a buried insulator layer 30b, 40b and a top semiconductor layer 30c, 40c. The handle substrate 30a may be removed after the top circuit 12 is bonded to the bottom circuit 14. The handle substrates 30a, 40a and the top semiconductor layers 30c, 40c may be composed of any suitable semiconductor material such as, for example, Si, Ge, SiGe, SiC, SiGeC, a III-V compound semiconductor, a II-VI compound semiconductor or any combinations thereof. Typically, each of the handle substrates 30a, 40a and the top semiconductor layers 30c, 40c may comprise a single crystalline semiconductor material, such as, for example, single crystalline silicon comprising any suitable crystallographic orientation (e.g., a (100), (110), (111), or (001) crystallographic orientation).

The buried insulator layers 30a, 40a may include a dielectric material such as silicon dioxide, silicon nitride, silicon oxynitride, boron nitride or a combination thereof. In one embodiment, the buried insulator layers 30a, 40a may be a buried oxide layer (BOX). The buried insulator layers 30a, 40a may be formed by a deposition process, such as chemical vapor deposition (CVD), plasma enhanced chemical vapor deposition (PECVD) or physical vapor deposition (PVD) or using a thermal growth process, e.g., thermal oxidation, to convert a surface portion of the handle substrates 30a, 40a. In yet another embodiment, the buried insulator layers 30a, 40a can be formed by implanting oxygen atoms into a bulk semiconductor substrate and thereafter annealing the structure.

For the top circuit 12, the plurality of transistors 12a, 12b, 12c, 12n are formed in series on the top semiconductor layer 30c. Similarly, for the bottom circuit 14, the plurality of transistors 14a, 14b, 14c, 14n are formed in series on the bottom semiconductor layer 40c. In embodiments, the plurality of transistors 12a, 12b, 12c, 12n may be at a minimum spacing, e.g., gate to contact (pc-ca) spacing, which can also be used to eliminate the need for capacitors in the top substrate 30. The spacing of the transistors 14a, 14b, 14c, 14n may also be a minimum spacing. It is also contemplated that different spacing can be provided between the transistors, whether uniform throughout the series of transistors or of different spacing depending on the desired performance characteristics of the device.

The transistors 12a, 12b, 12c, 12n, 14a, 14b, 14c, 14n may be conventional gate structures including, for example, single or multi-finger field effect transistors. For example, each transistor may comprise 200 fingers, compared to the conventional devices which have a single transistor on a single chip with 400 fingers. The gate structures include adjacent source and drain regions 16 with intervening capacitors 24a, 24b, 24c, 24d split between the top circuit 12 and the bottom circuit 14 as further described herein.

Although not critical to the understanding of the present disclosure, the gate structures can be fabricated using standard CMOS or replacement gate processes. In the standard CMOS processing, a gate dielectric and polysilicon are formed, e.g., deposited, onto the top semiconductor layer 30c, 40c, followed a patterning process. An insulator material such as nitride or oxide can be deposited on the patterned materials, followed by an anisotropic etching process to form sidewalls. In embodiments, the gate structures (transistors 12a, 12b, 12c, 12n) of the top substrate 30 may include a high-k dielectric material for; whereas the gate structures (transistors 14a, 14b, 14c, 14n) on the bottom substrate 40 may include a low-k dielectric material. The source and drain regions 16 may be formed by conventional ion implantation processes or an epitaxial growth process with an in-situ dopant (for raised source and drain regions) as is known in the art such that no further explanation is required for a complete understanding of the present disclosure.

Airgaps 50 may be formed over selected transistors 14a, 14b, 14c, 14n on the bottom substrate 40. In embodiments, the airgaps 50 may be formed over selected transistors such as the inner transistors, e.g., first and second transistors, in a stack of transistors; although other configurations are also contemplated herein. In additional or alternative embodiments, airgaps 60 may be formed above selected source/drain regions 16, adjacent to selected transistors 14a, 14b, 14c, 14n. In embodiments, the airgaps 60 may be formed over selected transistors such as the inner transistors, e.g., first and second transistors, in a stack of transistors; although other configurations are also contemplated herein. In further embodiments, the airgaps 50 and airgaps 60 may be combined in any combination, depending on the desired performance characteristics of the device.

Although not shown, the airgaps 50, 60 may also be provided in the top substrate 50 in any combination as described herein.

The transistors 12a, 12b, 12c, 12n and transistors 14a, 14b, 14c, 14n may be electrically connected together at their respective source regions and drain regions 16 by metallization features 18. In this way, the transistors 12a, 12b, 12c, 12n and the transistors 14a, 14b, 14c, 14n may be shared between the top substrate 30 and the bottom substrate 40. The metallization features 18 may comprise a plurality of different wiring layers and interconnect structures as should be understood by those of skill in the art.

A plurality of capacitors 24a, 24b, 24c, 24n may be formed from the metallization features 18 and, more specifically, by a top plate 18a and the bottom plate 18b of the metallization features 18. In more specific embodiments, the top plate 18a and the bottom plate 18b may be part of the metallization features 18 that electrically connect respective source and drain regions 16 of adjacent transistors 12a, 14a, 12b, 14b, 12c, 14c, 12n, 14n. For example, the top plate 18a and the bottom plate 18b overlap each other with an intervening insulator material 26 to form each of the capacitors 24a, 24b, 24c, 24n between the respective adjacent transistors 12a, 14a, 12b, 14b, 12c, 14c, 12n, 14n of the different circuits 12, 14 on the different substrates 30, 40. In this way, the plurality of capacitors 24a, 24b, 24c, 24n may be formed vertically between back end of the line structures of the bottom substrate 40 and the top substrate 30.

In embodiments, the top plate 18a and the bottom plate 18b may be wiring layers of each of the chips comprising metal material, e.g., copper, tungsten, aluminum, etc. The top plate 18a and the bottom plate 18b may be embedded within interlevel dielectric material 18 of the different substrates 30, 40. As the capacitors 24a, 24b, 24c, 24n are shared between the two substrates 30, 40, it is possible to reduce the size of the capacitors compared to the capacitors on only a single substrate. In addition, by sharing the capacitors 24a, 24b, 24c, 24n between the two substrates 30, 40, it is also possible to reduce the overall area requirement of the switch/tuner.

The metallization features 18 (including the top plate 18a and the bottom plate 18b) can be formed by various conventional lithography, etching and deposition methods known to those of skill in the art. For example, in conventional lithography, etching and deposition methods, a resist formed over a layer of insulator material (different layers of the interlevel dielectric material 28) is exposed to energy (light) and developed utilizing a conventional resist developer to form a pattern (opening). An etching process with a selective chemistry, e.g., reactive ion etching (RIE), will be used to transfer the pattern from the patterned photoresist layer to the different layers of the interlevel dielectric material 28 to form one or more trenches in the interlevel dielectric material 28 through the openings of the resist. Following the resist removal by a conventional oxygen ashing process or other known stripants (at each respective level or multiple levels in a dual damascene process), conductive material can be deposited by any conventional deposition processes, e.g., CVD processes. Any residual material on the surface of the interlevel dielectric material 28 can be removed by conventional chemical mechanical polishing (CMP) processes.

In embodiments, the capacitors 24a, 24b, 24c, 24n may be compensating metal-oxide-metal (MOM) capacitors provided between the top circuit 12 and the bottom circuit 14 and, more specifically, between the top substrate 30 comprising the top circuit 12 and the bottom substrate 40 comprising the bottom circuit 14. In embodiments, the plurality of capacitors 24a, 24b, 24c, 24n may have different capacitances, with a higher capacitance at the inner capacitors 24a, 24b, 24c and a lower capacitance at the outer capacitors 24n, etc.

The capacitors 24a, 24b, 24c, 24n may include an insulator material 26 between the top plate 18a and the bottom plate 18b. The insulator material 26 may bond the top substrate 30 to the bottom substrate 40 using bonding processes known to those of skill in the art. For example, the bonding process may be an oxide-oxide thermocompression direct bonding to assemble the multichip-to-substrate. More specifically, low-k dielectric material may be bonded together by a direct bonding technique and a high-k dielectric material may be bonded together by a thermal bonding technique.

The insulator material 26 may be either a high-k dielectric material or a low-k dielectric material or combinations thereof for different capacitors 24a, 24b, 24c, 24n, depending on the desired performance characteristics. For example, the low-k dielectric material may be oxide; whereas the high-k dielectric material may be, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof. In embodiments, the higher capacitance capacitors may use a high-k dielectric material between the top plate 18a and the bottom plate 18b and the lower capacitance capacitors may use a lower-k dielectric material between the top plate 18a and the bottom plate 18b.

As should be understood by those of skill in the art, prior to forming the metallization features 18 to the source and drain regions 16, a silicide process may be provided. The silicide process begins with deposition of a thin transition metal layer, e.g., nickel, cobalt or titanium, over fully formed and patterned semiconductor devices (e.g., source and drain regions 16 and respective devices (as required)). After deposition of the material, the structure is heated allowing the transition metal to react with exposed silicon (or other semiconductor material as described herein) in the active regions of the semiconductor device forming a low-resistance transition metal silicide. Following the reaction, any remaining transition metal is removed by chemical etching, leaving silicide contacts. It should be understood by those of skill in the art that silicide contacts will not be required on metal gate structures.

The switch can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw substrate form (that is, as a single substrate that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a top substrate comprising at least one top transistor and metal wiring structures; and
a bottom substrate comprising at least one bottom transistor and metal wiring structures, the bottom substrate being attached to the top substrate with the at least one top transistor being electrically connected to the at least one bottom transistor and a portion of the metal wiring structures of the top substrate and a portion of the metal wiring structures of the bottom substrate comprising at least one shared capacitor between the at least one top transistor and the at least one bottom transistor.

2. The structure of claim 1, wherein the shared capacitor comprises a metal oxide metal capacitor and the at least one bottom transistor comprises a switch.

3. The structure of claim 1, wherein the shared capacitor comprises a high-k dielectric between the metal wiring structures of the bottom substrate and the top substrate.

4. The structure of claim 3, wherein the top substrate is attached to the bottom substrate by the high-k dielectric material.

5. The structure of claim 1, wherein the shared capacitor comprises a low-k dielectric between the metal wiring structures of the bottom substrate and the top substrate.

6. The structure of claim 5, wherein the top substrate is attached to the bottom substrate by the low-k dielectric material.

7. The structure of claim 1, further comprising an airgap over the at least one transistor of the bottom substrate.

8. The structure of claim 7, wherein the top substrate is devoid of airgaps.

9. The structure of claim 1, wherein the bottom substrate comprises a high-resistivity handle substrate.

10. The structure of claim 1, wherein the at least one top transistor comprises a plurality of top transistors, the at least one bottom transistor comprises a plurality of bottom transistors and the at least one capacitor comprises a plurality of capacitors between respective transistors of the plurality of top transistors and transistors of the plurality of bottom transistors.

11. The structure of claim 10, wherein the respective transistors of the plurality of top transistors and the transistors of the plurality of bottom transistors are electrically connected to each other by respective source regions and drain regions, and the plurality of capacitors are between the respective source regions and drain regions of the plurality of bottom transistors and the plurality of top transistors adjacent at an attachment location of the top substrate and the bottom substrate.

12. The structure of claim 11, wherein the plurality of top transistors are in series and the plurality of bottom transistors are in series.

13. A structure comprising:
a top substrate comprising a plurality of top transistors in series, each of the top transistors having a source region and a drain region;
a bottom substrate comprising a plurality of bottom transistors in series, each of the bottom transistors having a source region and a drain region; and
a plurality of capacitors electrically shared between the top transistors and the bottom transistors.

14. The structure of claim 13, wherein the plurality of capacitors comprises a top plate and a bottom plate, the top plate comprises wiring structures of the top substrate and the bottom plate comprises wiring structures of the bottom substrate.

15. The structure of claim 14, wherein the wiring structures of the top substrate and the wiring structures of the bottom substrate electrically connect the source regions of the plurality of top transistors to source regions of the plurality of bottom transistors and drain regions of the plurality of top transistors to drain regions of the plurality of bottom transistors.

16. The structure of claim 15, wherein the plurality of capacitors are overlapping plates of the wiring structures of the top substrate and the wiring structures of the bottom substrate with an insulator material therebetween attaching the top substrate to the bottom substrate.

17. The structure of claim 14, wherein the plurality of capacitors include a high-k dielectric material between the top plate and the bottom plate.

18. The structure of claim 14, wherein the plurality of capacitors include a low-k dielectric material between the top plate and the bottom plate.

19. The structure of claim 14, wherein the top substrate comprises a high resistivity substrate and airgaps are provided over at least one of the plurality of bottom transistors.

20. A method comprising:
forming a top substrate comprising at least one top transistor and metal wiring structures;
forming a bottom substrate comprising at least one bottom transistor and metal wiring structures; and
attaching the bottom substrate to the top substrate with the at least one top transistor being electrically connected to the at least one bottom transistor and a portion of the metal wiring structures of the top substrate and a portion of the metal wiring structures of the bottom substrate forming at least one shared capacitor between the at least one top transistor and the at least one bottom transistor.
